(19) United States
(12) Patent Application Publication
(10) Pub. No.: US 2014/0139249 A1
(43) Pub. Date: May 22, 2014

(54) APPARATUS AND A METHOD FOR DETECTING DEFECTS WITHIN PHOTOVOLTAIC MODULES

(71) Applicant: PRIMESTAR SOLAR, INC., Arvada, CO (US)

(72) Inventors: Weston Alan Dobson, Arvada, CO (US); Douglas Garth Jensen, Lakewood, CO (US)

(73) Assignee: PRIMESTAR SOLAR, INC., Arvada, CO (US)

(21) Appl. No.: 13/681,822

(22) Filed: Nov. 20, 2012

(51) Int. Cl. G01R 31/26; G01R 1/067

(52) U.S. Cl. CPC G01R 31/2605; G01R 1/06711
USPC 324/755.01; 324/761.01

(57) ABSTRACT

An apparatus and a method for detecting defects within a photovoltaic module are provided. To detect defects within the photovoltaic module, light from a light source is directed towards the photovoltaic module. The light generates a voltage within each solar cell of the photovoltaic module. The generated voltages are measured and compared in order to detect defects within the solar cells of the photovoltaic module.

### FIELD OF THE INVENTION

The present subject matter relates generally to photovoltaic modules and methods for detecting defects within the same.

### BACKGROUND OF THE INVENTION

Thin film photovoltaic modules are gaining acceptance and interest within the solar industry. Thin film photovoltaic modules can be formed by deposition of various semiconductor thin films and electrode thin films on a substrate. Such photovoltaic modules also undergo various processing steps in order to define a plurality of individual solar cells on the thin films. For example, certain photovoltaic modules undergo laser scribing processes to define and isolate individual solar cells on the photovoltaic module's thin films, to define a perimeter edge zone around the solar cells, and to connect the solar cells in series.

During formation, electrical defects, e.g., shunts, can manifest within the photovoltaic module's thin films. Such defects can negatively affect the photovoltaic module's performance. For example, such defects can reduce the current generated by the photovoltaic module and/or the voltage from the photovoltaic module. Thus, detecting and locating such defects can assist with improving the photovoltaic module's performance.

However, electrical defects can be difficult to detect by visual inspection. Certain systems for detecting electrical defects within a photovoltaic module include running current through the module and capturing images of the module in a non-visible spectrum, such as infrared, after the current has heated up or excited the module. Electrical defects within the module tend to concentrate current at the defects because of their lower resistance. The defects tend to become hotter than other areas of the module and show up as “hot spots” in the infrared spectrum.

Such systems can be effective but have certain drawbacks. In particular, such systems can require a significant wait time in order for the module to heat up due to the electrical current. The systems also produce an image as an output. Thus, automated defect counting and/or locating can require sophisticated image processing software. Also, it can be difficult to quantify the defect's impact on module performance from such images.

Accordingly, an apparatus and method for quickly and efficiently detecting electrical defects through electrical means within photovoltaic modules would be useful.

### BRIEF DESCRIPTION OF THE INVENTION

The present subject matter provides an apparatus and a method for detecting defects within a photovoltaic module. To detect defects within the photovoltaic module, light from a light source is directed towards the photovoltaic module. The light generates a voltage within each solar cell of the photovoltaic module. The generated voltages are measured and compared in order to detect defects within the solar cells of the photovoltaic module. Additional aspects and advantages of the invention will be set forth in part in the following description, or may be apparent from the description, or may be learned through practice of the invention.

In a first exemplary embodiment, a method for detecting defects within a photovoltaic module having a plurality of thin films that defines a plurality of solar cells connected in series is provided. The method includes directing light from a light source towards the photovoltaic module. The light has an intensity of greater than zero watts per meter squared to about fifty watts per meter squared. The light generates a voltage within at least one solar cell of the photovoltaic module. The method also includes measuring the voltage of the at least one solar cell of the photovoltaic module.

In a second exemplary embodiment, an apparatus for detecting defects within a photovoltaic module is provided. The photovoltaic module has a plurality of thin films that defines a plurality of solar cells connected in series. The apparatus includes a light source configured for directing light having an intensity greater than zero watts per meter squared to about fifty watts per meter squared towards the plurality of solar cells of the photovoltaic module. A probe head has a plurality of contacts. Each contact of the plurality of contacts is configured for being positioned in electrical communication with a respective one of the plurality of solar cells of the photovoltaic module. A measuring unit is in electrical communication with the probe head. The measuring unit is configured for measuring a voltage of each solar cell of the plurality of solar cells.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 provides a top, plan view of a thin film photovoltaic module according to an exemplary embodiment of the present subject matter;

FIG. 2 provides a cross-sectional view of the thin film photovoltaic module of FIG. 1 taken along the 2-2 line of FIG. 1;

FIG. 3 provides a perspective view of an apparatus for detecting defects within a photovoltaic module according to an exemplary embodiment of the present subject matter;

FIG. 4 provides a perspective view of the apparatus of FIG. 3 with covers of the apparatus removed to reveal a testing chamber of the apparatus;

FIG. 5 provides a side, elevation view of the apparatus of FIG. 3;

FIG. 6 provides an exemplary I-V plot for a photovoltaic module in which the photovoltaic module is exposed to light having an intensity of about five-hundred watts per meter squared;

FIG. 7 provides an exemplary I-V plot for the photovoltaic module of FIG. 6 in which the photovoltaic module is exposed to light having an intensity of about five watts per meter squared;

FIG. 8 provides an image of a photovoltaic module with the photovoltaic module heated due to a current flowing through the photovoltaic module;

FIG. 9 provides a graph of voltages for each cell of the photovoltaic module of FIG. 8 at a particular location on the photoelectric module with the photovoltaic module exposed to light having an intensity of about five watts per meter squared;

FIG. 10 provides a graph of voltages for each cell of the photovoltaic module of FIG. 8 at the particular location on the photoelectric module with the photovoltaic module exposed to light having an intensity of about five-hundred watts per meter squared;

FIG. 11 illustrates a method for detecting defects within a photovoltaic module according to an exemplary embodiment of the present subject matter; and

FIG. 12 illustrates a method for detecting defects within a plurality of photovoltaic modules according to an exemplary embodiment of the present subject matter.

### DETAILED DESCRIPTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

In the present disclosure, when a layer is being described as “on” or “over” another layer or substrate, it is to be understood that the layers can either be directly contacting each other or have another layer or feature between the layers, unless otherwise stated. Thus, these terms are simply describing the relative position of the layers to each other and do not necessarily mean “on top of” since the relative position above or below depends upon the orientation of the device to the viewer. Additionally, although the invention is not limited to any particular film thickness, the term “thin” describing any film layers of the photovoltaic device generally refers to the film layer having a thickness less than about 10 micrometers (“microns” or “μm”).

It is to be understood that the ranges and limits mentioned herein include all ranges located within the prescribed limits (i.e., subranges). For instance, a range from about 100 to about 200 also includes ranges from 110 to 150, 170 to 190, 153 to 162, and 145.3 to 149.6. Further, a limit of up to about 7 also includes a limit of up to about 5, up to 3, and up to about 4.5, as well as ranges within the limit, such as from about 1 to about 5, and from about 3.2 to about 6.5.

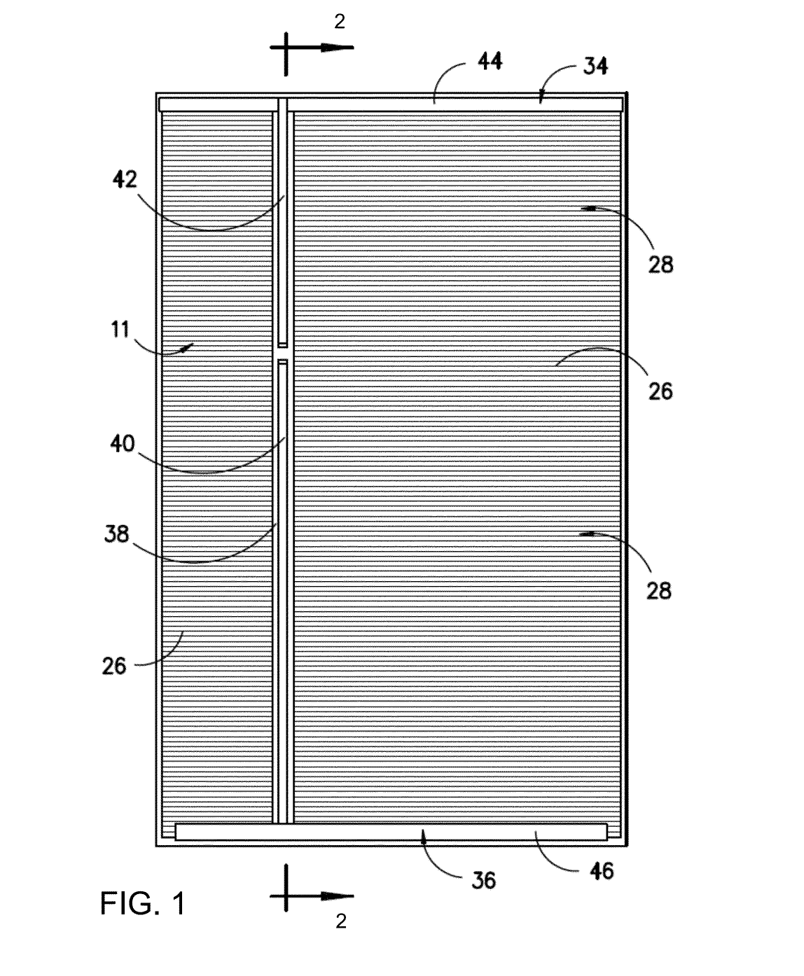

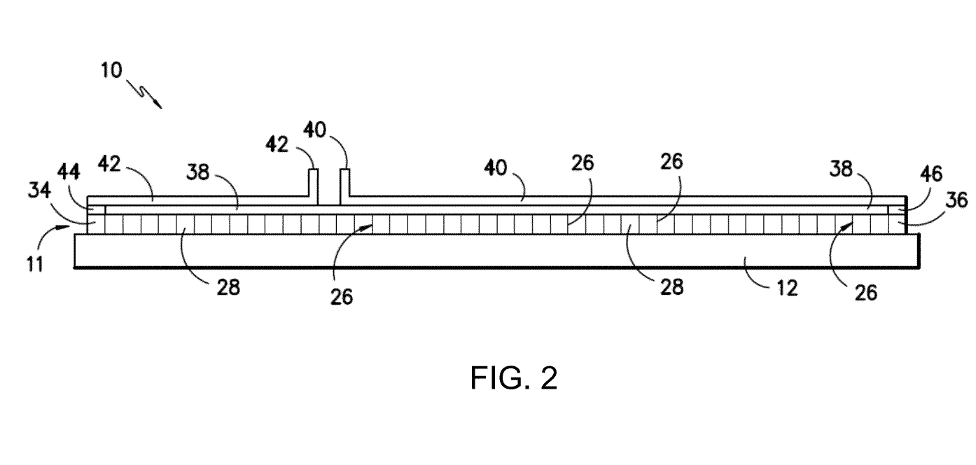

FIG. 1 provides a top, plan view of a thin film photovoltaic module 10 according to an exemplary embodiment of the present subject matter. FIG. 2 provides a cross-sectional view of photovoltaic module 10 taken along the 2-2 line of FIG. 1. It should be understood that photovoltaic module 10 is provided by way of example only and that various alternative thin film photovoltaic modules are within the scope of the present subject matter. Accordingly, any suitable thin film photovoltaic module may be employed in alternative exemplary embodiments.

Photovoltaic module 10 includes a transparent substrate 12 (e.g., a glass substrate). In the present exemplary embodiment, substrate 12 may be referred to as a “superstrate,” as it is the substrate on which subsequent layers of photovoltaic module 10 are formed even though it faces upward to the radiation source (e.g., the sun) when photovoltaic module 10 is in use. Substrate 12 may be constructed of any suitable material, e.g., a high-transmission glass, such as high transmission borosilicate glass, low-iron float glass, or other highly transparent glass material. Substrate 12 is generally thick enough to provide support for subsequent film layers (e.g., from about 0.5 mm to about 10 mm thick), and is substantially flat to provide a good surface for forming the subsequent film layers.

A plurality of thin film layers 11 is positioned on substrate 12. Thin film layers 11 define individual solar cells 28 (also referred to as photovoltaic cells) separated by scribes 26 to collectively form a plurality of serially connected solar cells. Specifically, solar cells 28 are electrically connected together in series. Solar cells 28 extend between a first terminal cell 34 and a second terminal cell 36. First terminal cell 34 and second terminal cell 36 are positioned on opposite ends of photovoltaic module 10, e.g., the first and last cells of solar cells 28. A back contact of first terminal cell 34 serves as an electrical connector for the photovoltaic module 10, while a transparent conductive oxide layer of second terminal cell 36 serves as the opposite electrical connector for photovoltaic module 10.

In various exemplary embodiments, thin film layers 11 can include a transparent conductive oxide layer (e.g., cadmium stannate or a stoichiometric variation of cadmium, tin, and oxygen; or doped tin oxide, etc.) on substrate 12, a resistive transparent buffer layer (e.g., a combination of zinc oxide and tin oxide) on the transparent conductive oxide layer, an n-type layer on the resistive transparent buffer layer, a p-type layer on the n-type layer, and a back contact on the p-type layer. The n-type layer can include cadmium sulfide (i.e., a cadmium sulfide thin film layer), and the p-type layer can include cadmium telluride (i.e., a cadmium telluride thin film layer). Generally, the back contact defines the exposed surface of thin film layers 11, and serves as an electrical contact for thin film layers 11 opposite the front contact, as defined by the transparent conductive oxide layer.

As discussed above, solar cells 28 are separated by scribes 26. In the exemplary embodiment shown in FIG. 1, scribes 26 are substantially parallel to one another such that solar cells 28 are substantially the same size. Further, each one of scribes 26 is generally oriented in the x-direction, e.g., each scribe of scribes 26 extends longitudinally in the x-direction. In alternative exemplary embodiments, scribes 28 may have any suitable orientation and/or size.

An insulating layer 38 is positioned on thin film layers 11, e.g., to protect the back contact of thin film layers 11. Insulating layer 38 generally includes an insulating material that prevents or hinders electrical conductivity therethrough. Insulating layer 38 can be coated on both surfaces with an adhesive. The adhesive can allow for bonding of insulating layer 38 to the underlying thin film layers 11 and for bonding of conductive strips 40 and 42 to insulating layer 38. Any suitable material can be used to produce or construct insulating layer 38. For example, insulating layer 38 can include a polymeric film, such as polyethylene terephthalate (PET). Similarly, the adhesive can be any suitable material, such as an acrylic adhesive or a thermosetting acrylic adhesive.

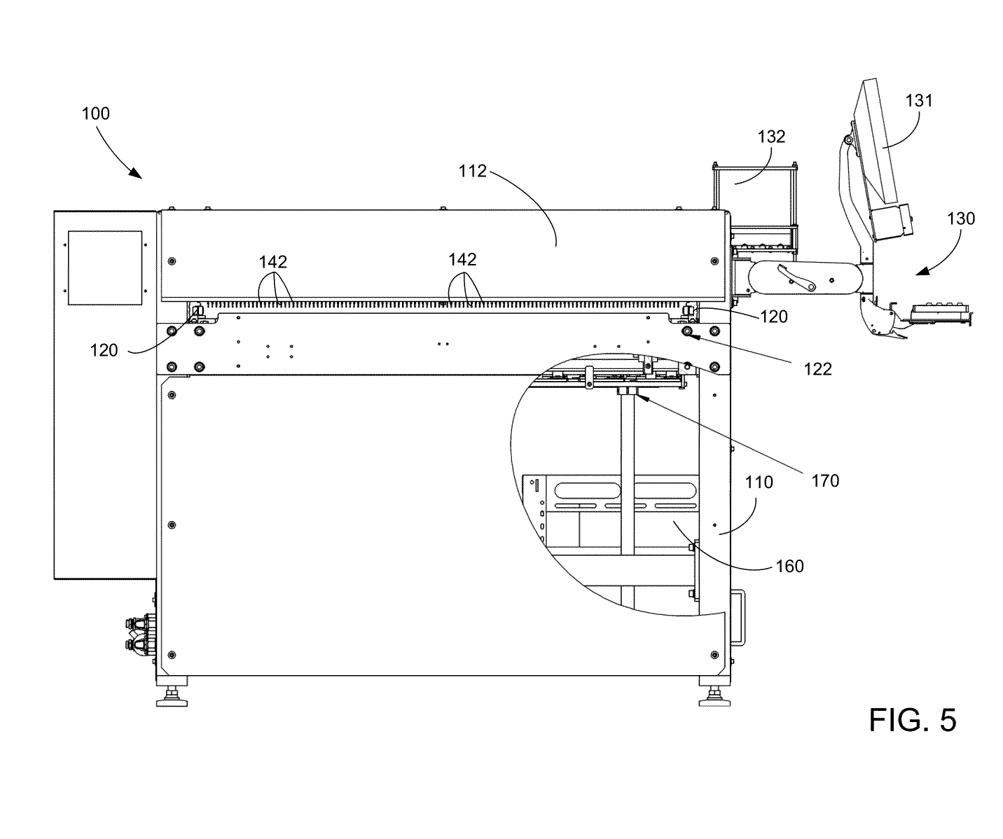

In one particular embodiment, insulating layer 38 is a strip of insulating material generally oriented in a direction perpendicular to the orientation of scribes 26. For example, in the exemplary embodiment shown in FIG. 5, insulating layer 38 is generally oriented in the y-direction that is perpendicular to the orientation of scribes 26 in the x-direction, e.g., insulating layer 38 extends longitudinally in the y-direction. Insulating layer 38 can have a thickness in the z-direction suitable to prevent electrical conductivity from the underlying thin film layers 11, particularly the back contact, to any subsequently applied layers. In one particular embodiment, insulating layer 38 can prevent electrically conductivity between thin film layers 11 and conductive strips 40 and 42.

Conductive strips 40 and 42 are applied over insulating layer 38. Conductive strips 40 and 42 can be constructed from any suitable material. For example, conductive strips 40 and 42 may be constructed with a conductive metal foil.

Bus bars 44 and 46 are mounted over first and second terminal cells 34 and 36, respectively, to serve as opposite electrical connections. Further, an encapsulating substrate (not shown) can be adhered to photovoltaic module 10 via an adhesive layer (not shown). The adhesive layer is generally positioned over conductive strips 40 and 42, insulating layer 38, and any remaining exposed areas of thin film layers 11. For example, the adhesive layer can define an adhesive gap that generally corresponds to a connection aperture defined by the encapsulating substrate. As such, conductive strips 40 and 42 can extend through the adhesive gap. The adhesive layer can generally protect thin film layers 11 and attach the encapsulating substrate to photovoltaic module 10. The adhesive layer can be constructed from ethylene vinyl acetate (EVA), polyvinyl butyral (PVB), silicone based adhesives, or other adhesives which are configured to prevent moisture from penetrating the device.

A junction box (not shown) can also be included in photovoltaic module 10 and can be configured to electrically connect photovoltaic module 10 by completing the DC circuit.

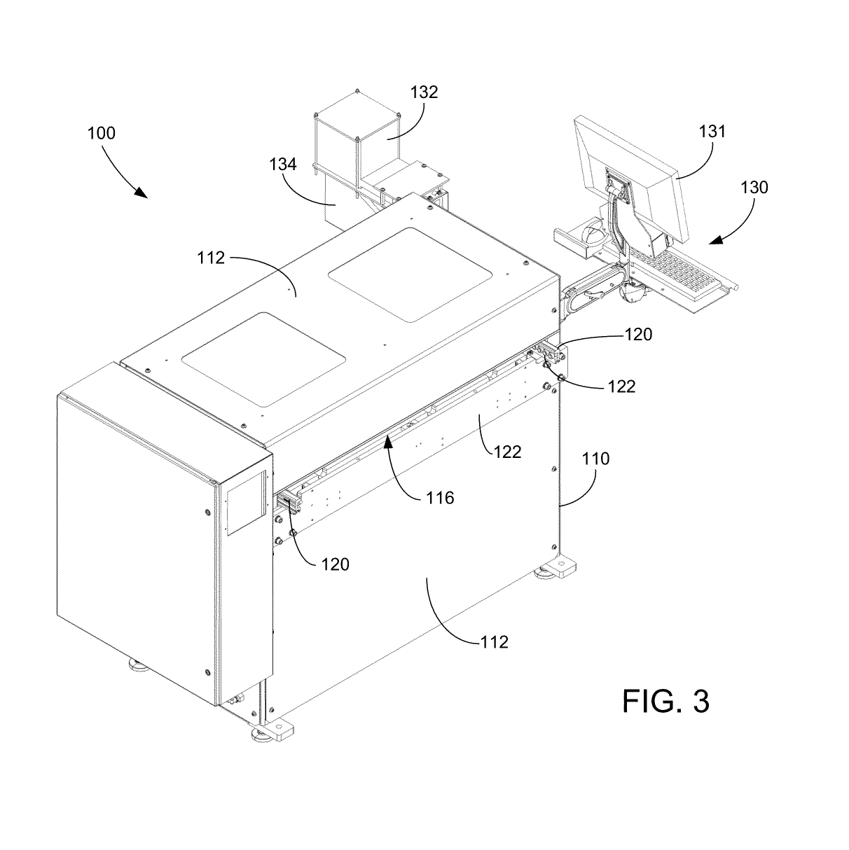

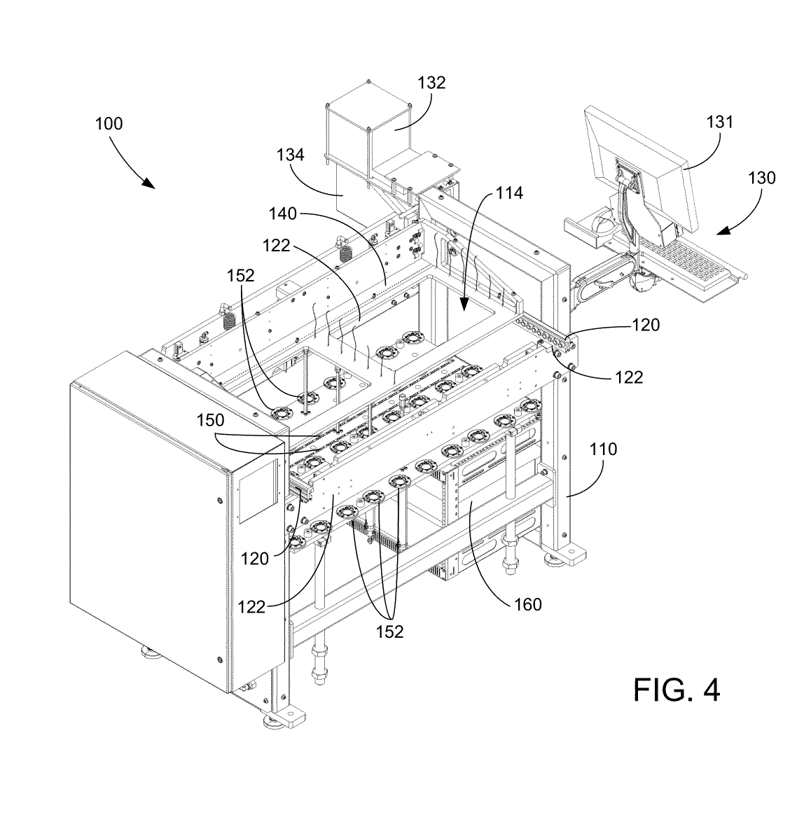

FIG. 3 provides a perspective view of an inline photovoltaic module profiler or apparatus 100 according to an exemplary embodiment of the present subject matter. FIG. 4 provides a perspective view of apparatus 100 with covers 112 of apparatus 100 removed to reveal a testing chamber 114 of apparatus 100. FIG. 5 provides a side, elevation view of apparatus 100. Apparatus 100 is configured for detecting defects within a photovoltaic module, such as photovoltaic module 10 (FIG. 1).

As will be understood by those skilled in the art, photovoltaic module 10 can includes defects or imperfections that negatively affect performance of photovoltaic module 10. For example, photovoltaic module 10 can include defects that cause localized shunting within photovoltaic module 10. As will be understood by those skilled in the art, such defects can include a bridged scribe 28, a pin hole within the semiconductor layers of photovoltaic module 10, and/or a gap within the photo-resist coverage applied to the semiconductor layers.

Such defects can arise during manufacture of photovoltaic module 10. Detecting and locating such defects can, e.g., permit elimination or remediation of such defects within subsequently produced photovoltaic modules, thereby improving performance of such photovoltaic modules. Apparatus 100 is configured to detect and/or locate defects within photovoltaic module 10. Apparatus 100 can scan photovoltaic module 10 and locate defects thereon, e.g., prior to applying conductive strips 40 and 42, bus bars 44 and 46, the adhesive layer, and/or the encapsulating substrate onto solar cells 28.

Apparatus 100 includes a frame or casing 110 that supports covers 112. Apparatus 100, e.g., casing 110 and/or covers 112, defines testing chamber 114 that is configured for receipt of photovoltaic module 10 during testing of the same. In particular, apparatus 110 defines an entrance 116 and also includes a conveyor 120 for guiding photovoltaic module 10 therethrough. Entrance 116 permits access to testing chamber 114 such that photovoltaic module 10 can slide through entrance 116 in order to enter testing chamber 114. As an example, conveyor 120 can engage photovoltaic module 10 at entrance 116. Conveyor 120 can slide or move photovoltaic module through entrance 116 such that photovoltaic module 10 is received within testing chamber 114. With photovoltaic module 10 received within testing chamber 114, apparatus 100 can test photovoltaic module 10 for defects as described in greater detail below.

Apparatus 100 includes a pair of supports 122 positioned on opposite ends of testing chamber 114. Supports 122 can slide upwardly to engage and support photovoltaic module 10 and hinder movement of photovoltaic module 10 during testing. After testing of photovoltaic module 10 is complete, supports 122 can slide downwardly such that photovoltaic module 10 rests on rollers 121 of conveyer 120. Conveyer 120 can then remove photovoltaic module 10 from testing chamber 114 by sliding photovoltaic module out of an exit (not shown) of apparatus 100. The exit is positioned on an opposite end of testing chamber 114 relative to entrance 116 such that photovoltaic module 10 enters apparatus on one side of testing chamber 114 and exits on an opposite side of testing chamber 114.

Apparatus 100 includes light sources, such as light emitting diodes or incandescent bulbs, for directing light towards photovoltaic module 10 when photovoltaic module 10 is positioned within testing chamber 114. In particular, apparatus 100 includes a plurality of high intensity light sources 152 and a plurality of low intensity light sources 150 positioned within testing chamber 114. High intensity light sources 152 are configured for directing light having an intensity greater than about one hundred watts per meter squared towards photovoltaic module 10, e.g., towards solar cells 28. In one exemplary embodiment, high intensity light sources 152 can direct light having an intensity of about five hundred watts per meter squared or about half a sun towards photovoltaic module 10. In another exemplary embodiment, high intensity light sources 152 can direct light having an intensity greater than about one thousand watts per meter squared or about a sun towards photovoltaic module 10. Conversely, low intensity light sources 150 are configured for directing light having an intensity greater than zero watts per meter squared and less than about fifty watts per meter squared towards photovoltaic module 10, e.g., towards solar cells 28. In one exemplary embodiment, low intensity light sources 150 can direct light having an intensity of about five watts per meter squared or about five thousandths of a sun towards photovoltaic module 10. In another exemplary embodiment, low intensity light sources 150 can direct light having an intensity between about one watt per meter squared and about ten watts per meter squared towards photovoltaic module 10. In an additional exemplary embodiment, low intensity light sources 150 can direct light having an intensity between about two or three watts per meter squared and about eight or nine watts per meter squared towards photovoltaic module 10.

When low and/or high intensity light sources 150 and 152 direct light towards photovoltaic module 10 within testing chamber 114, solar cells 28 generate a current and/or a voltage. Thus, photovoltaic module 10 operates within testing chamber 114, such that electrical production properties of photovoltaic module 10 can be determined by apparatus 10 as discussed in greater detail below.

Apparatus 100 also includes a probe head 140. Probe head 140 includes a plurality of contacts 142 (FIG. 5). Each contact of contacts 142 is configured for being positioned in electrical communication with a respective one of solar cells 28 of photovoltaic module 10. As an example, when photovoltaic module 10 is positioned within testing chamber 114 and held by supports 122, probe head 140 can move downwardly to position contacts 142 in electrical communication with solar cells 28. Thus, with photovoltaic module 10 supported on supports 122 and at least one of low and high intensity light sources 150 and 152 directing light towards photovoltaic module 10, contacts 142 can act as an electrode for each respective one of solar cells 28.

Apparatus 100 also includes features for measuring voltages of solar cells 28, e.g., when at least one of low and high intensity light sources 150 and 152 direct light towards photovoltaic module 10. In particular, apparatus 100 includes a measuring unit 134 that is in electrical communication with probe head 140. Measuring unit 134 is configured for measuring a voltage of solar cells 28. In various exemplary embodiments, measuring unit 134 can include a source measurement unit, such as a sourcemeter, or a multimeter.

Apparatus 100 further includes a multiplexer 132, e.g., a two wire multiplexer or a matrix multiplexer. Multiplexer 132 is configured for selectively placing pairs of contacts 142 in electrical communication with measuring device 134. As an example, multiplexer 132 can sequentially place a pair of contacts 142 in electrical communication with measuring device 134. Thus, measuring device 134 can sequentially measure the voltages of solar cells 28 via contacts 142 and multiplexer 132.

Apparatus 100 also includes a controller 160 that is operatively coupled or in communication with various components of apparatus 100, e.g., low and high intensity light sources 150 and 152, measuring unit 134, multiplexer 132, and/or supports 122. As an example, controller 160 can receive and record signals from measuring device 134 where each signal corresponds to a voltage of a respective solar cell 28. Controller 160 is also configured for operating such components of apparatus 100. Thus, controller 160 can selectively activate or deactivate low and high intensity light sources 150 and 152, measuring unit 134, multiplexer 132, and/or supports 122.

Controller 160 may include a memory and one or more microprocessors, CPUs or the like, such as general or special purpose microprocessors operable to execute programming instructions or micro-control code associated with operation of apparatus 100. The memory may represent random access memory such as DRAM, or read only memory such as ROM or FLASH. In one embodiment, the processor executes programming instructions stored in memory. The memory may be a separate component from the processor or may be included onboard within the processor. Alternatively, the instructions can be implemented by hard-wired logic or other circuitry, including, but not limited to application-specific circuits.

Controller 160 may be positioned in a variety of locations throughout apparatus 100. Input/output (“I/O”) signals may be routed between controller 160 and various operational components of apparatus 100. The components of apparatus 100 may be in communication with controller 160 via one or more signal lines or shared communication busses.

Controller 160 may be programmed to operate apparatus 100. In particular a user may utilize a user interface 130 to input commands to controller 160. Thus, user interface 130 is configured for permitting a user to manage operation of apparatus 100. User interface 130 may include any suitable type of interface such as a touch screen, knobs, sliders, buttons, speech recognition, etc., that permits a user to input control commands for apparatus 100. User interface 130 also includes a display 131, e.g., for visually providing test data from apparatus 100 to a user.

As discussed above, apparatus 100 is configured for detecting and/or locating defects within a photovoltaic module, such as photovoltaic module 10. Thus, a user can utilize user interface 130 to initiate a scan for defects on photovoltaic module 10. Operation of apparatus 100 is discussed in greater detail below.

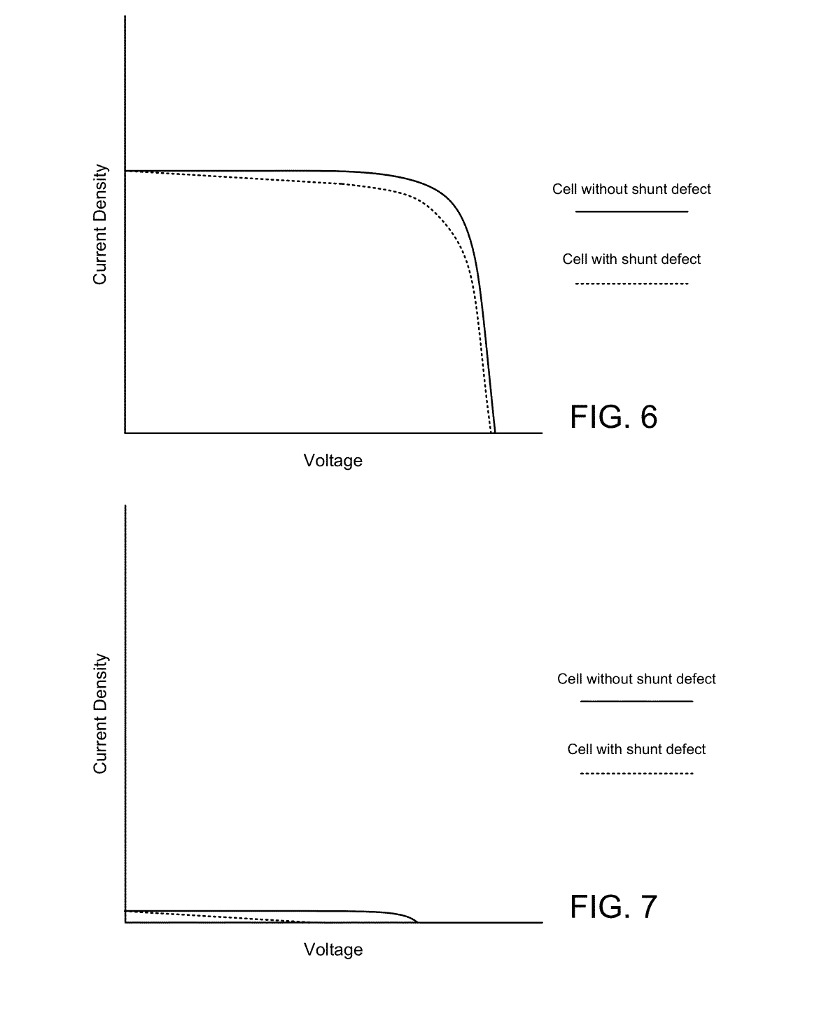

FIG. 6 provides an exemplary I-V plot for photovoltaic module 10 in which photovoltaic module 10 is exposed to light having an intensity of about five-hundred watts per meter squared. Thus, in FIG. 6, high intensity light sources 152 direct light towards photovoltaic module 10. FIG. 7 provides an exemplary I-V plot for photovoltaic module 10 in which photovoltaic module 10 is exposed to light having an intensity of about five watts per meter squared. Thus, in FIG. 7, low intensity light sources 150 direct light towards photovoltaic module 10. As may be seen in FIGS. 6 and 7, when relatively high intensity light, e.g., light having an intensity of about five hundred watts per meter squared, is directed towards photovoltaic module 10, photovoltaic module 10 generates more current relative to when relatively low intensity light, e.g., light having an intensity of about five watts per meter squared, is directed towards photovoltaic module 10.

FIGS. 6 and 7 each provide I-V plots for a solar cell with a relatively high shunt resistance, e.g., a solar cell without a shunt defect, and for a solar cell with a relatively low shunt resistance, e.g., a solar cell with a shunt defect. As may be seen in FIG. 6, a voltage difference between the solar cell without the shunt defect and the solar cell with the shunt defect is small and can be difficult to detect when photovoltaic module 10 is in an open circuit configuration and exposed to relatively high intensity light. Conversely, as may be seen in FIG. 7, the voltage difference between the solar cell without the shunt defect and the solar cell with the shunt defect is larger and can be easier to detect when photovoltaic module 10 is in an open circuit configuration and exposed to relatively low intensity light.

Without wishing to be bound to any theory, it is believed that low intensity light increases the sensitivity of the solar cell voltages to shunting defects. With a sufficiently low intensity, the voltage of a solar cell with a shunt defect is the product of the photocurrent such solar cell produces and the electrical resistance of the shunt. As the photocurrent is proportional to the intensity of the light and unaffected by shunt defects, increasing the illumination will increase this product. If the product is greater than the “turn-on” voltage of such solar cell, the cell voltage will be dominated by the “turn-on” voltage and the influence of shunting will be minimal. Furthermore, the higher photocurrent associated with high intensity light can create voltage differences from one part of a cell to another as the current travels to the shunt defect. This will effectively limit the impact of shunts on voltage to the region immediately surrounding the shunt and can also alter the voltage of surrounding solar cells.

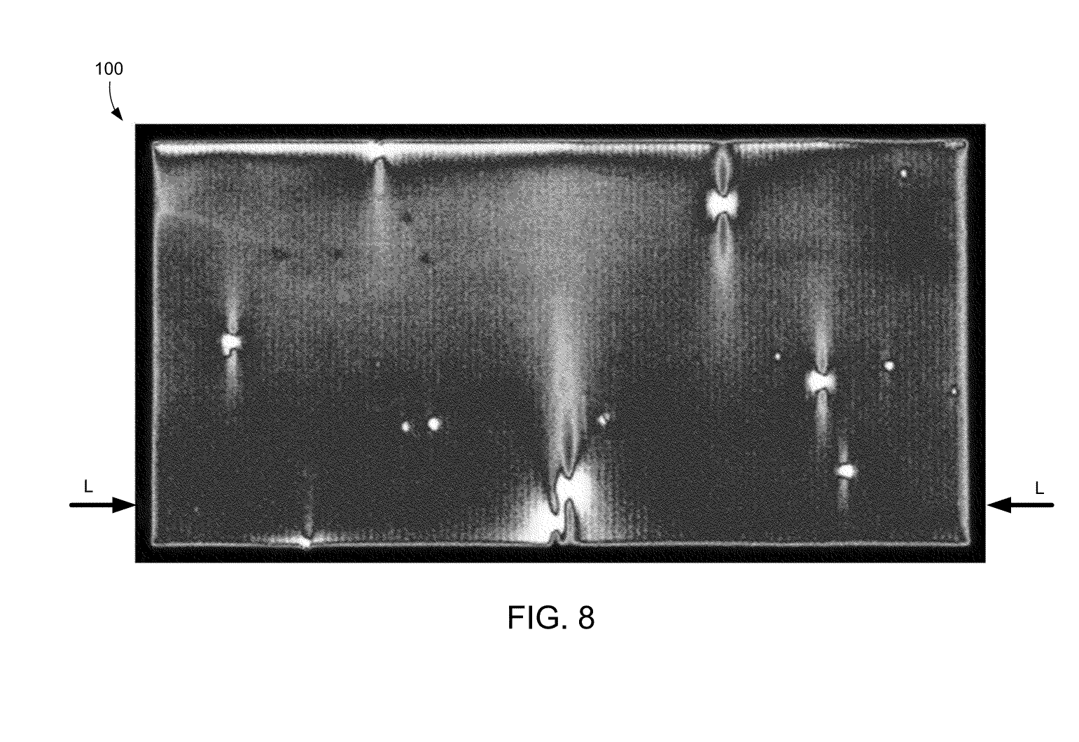

FIG. 8 provides an image of photovoltaic module 10 with photovoltaic module 10 heated due to a current flowing through photovoltaic module 10. As will be understood by those skilled in the art, the image of FIG. 8 is taken in a non-visible spectrum (e.g., the infrared spectrum) after running current through photovoltaic module 10 and giving the current time to heat up or excite photovoltaic module 10. Electrical defects in solar cells 28 of photovoltaic module 10 tend to concentrate current into small areas because of the associated lower resistance. Such areas tend to become hotter than other areas and show up as ‘hot spots’ in the infrared spectrum. Thus, in FIG. 8, the relatively darker areas have higher shunt resistances and the relatively light areas have lower shunt resistances. For example, the white areas in FIG. 8 correspond to shunt defects in photovoltaic module 10.

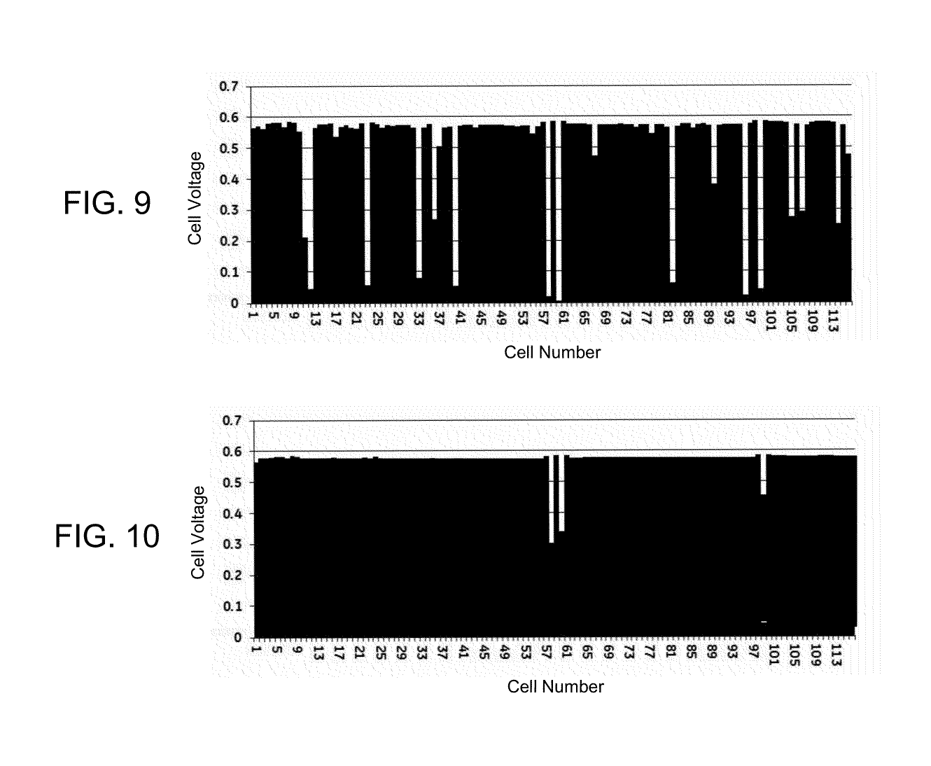

FIG. 9 provides a graph of voltages for each solar cell 28 of photovoltaic module 10 at a particular location (labeled with arrows L in FIG. 8) on photoelectric module 10. In FIG. 9, photovoltaic module 10 is exposed to light from low intensity light sources 150 having an intensity of about five watts per meter squared. Conversely, FIG. 10 provides a graph of voltages for each solar cell 28 of photovoltaic module 10 at the particular location L on photoelectric module 10 with photovoltaic module 10 exposed to light from high intensity light sources 152 having an intensity of about five hundred watts per meter squared. The graphs shown in FIGS. 9 and 10 may be presented on display 131 of apparatus 100 after completion of a scan for defects by photovoltaic module 10.

As shown in FIG. 9, a scan for defects conducted by apparatus 100 with light having an intensity of about five watts per meter squared is more sensitive than a scan for defects conducted by apparatus 100 with light having an intensity of about five hundred watts per meter squared. As an example, photovoltaic module 10 may be loaded in testing chamber 114 as described above. Within testing chamber 114, low and/or high intensity light sources 150 and 152 direct light towards photovoltaic module 10 in order to generate a voltage within each solar cell 28 of photovoltaic module 10. Contacts 142 of probe head 140 permit measuring unit 134 to measure the voltage of each solar cell 28. In particular, each contact of contacts 142 touches each respective solar cell 28 at the particular location shown in FIG. 7 in order to permit measuring unit 134 to measure the voltage of each solar cell 28. Controller 160 can receive such measurements and display them visually as graphs, e.g., the graphs shown in FIGS. 8 and 9.

When high intensity light sources 152 operate with an intensity of about five hundred watts per meter squared as shown in FIG. 8, defects located away from probe head 140 are not easily detectable. However, defects in close proximity to probe head 140 may be easily detected due to the voltage drop measured by probe head 140. Conversely, when low intensity light sources 150 operate with an intensity of about five watts per meter squared as shown in FIG. 9, defects located away from probe head 140 and located proximate probe head 140 are readily apparent on the graph because of the corresponding voltage drop associated with such defects. Thus, operating low intensity light sources 150 during the scan for defects can assist with identifying defects on photovoltaic module 10. In particular, directing light having an intensity less than about fifty watts per meter squared can permit apparatus 100 to detect defects located away from probe head 140 without having to move probe head 140 to multiple locations on photovoltaic module 10. Thus, probe head 140 can remain stationary relative to photovoltaic module 10 during a scan for defects by apparatus 100.

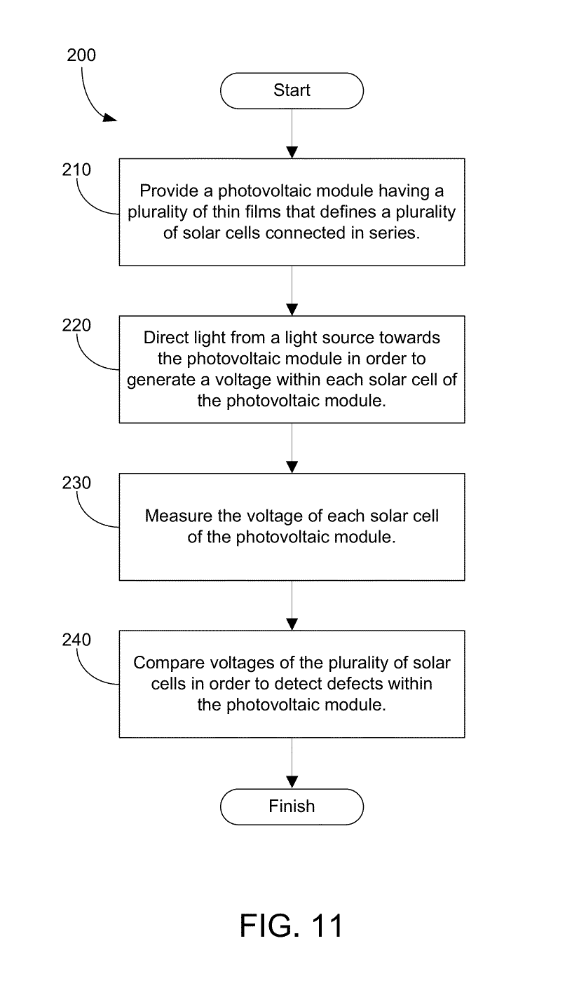

FIG. 11 illustrates a method 200 for detecting defects within a photovoltaic module, such as photovoltaic module 10 (FIG. 1), according to an exemplary embodiment of the present subject matter. Method 200 may be implemented or executed by controller 160 of apparatus 100 (FIG. 3). Utilizing method 200, apparatus 100 can detect and locate defects within solar cells 28 of photovoltaic module 10.

At step 210, photovoltaic module 10 is provided. As discussed above, photovoltaic module 10 includes plurality of thin film layers 11 that defines plurality of solar cells 28 connected in series. As an example, apparatus 100 may be disposed in-line on an assembly line for photovoltaic module 10. During production, apparatus 100 can receive photovoltaic module 10 in order to test photovoltaic module 10 for defects. Thus, at step 210, controller 160 can activate conveyer 120 in order to pull photovoltaic module 10 through entrance 116 of apparatus 100 such that photovoltaic module 10 is inserted into testing chamber 114.

At step 220, with photovoltaic module 10 positioned within testing chamber 114 of apparatus 100, controller 160 can activate low intensity light sources 150 such that low intensity light sources 150 direct light towards photovoltaic module 10, e.g., solar cells 28 of photovoltaic module 10. During step 220, light from low intensity light sources 150 has an intensity less than about fifty watts per meter squared. Further, the light from low intensity light sources 150 generates a voltage within each solar cell of solar cells 28.

At step 230, the voltage of each solar cell of solar cells 28 is measured. For example, contacts 142 of probe head 140 can be placed in electrical communication with a respective one of solar cells 28 in order to permit measuring unit 134 to measure voltages of each one of solar cells 28. At step 230, controller 160 can receive and record voltage measurements from measuring unit 134.

At step 240, controller 160 compares voltages of solar cells 28 in order to detect defects within solar cells 28 of photovoltaic module 10. As an example, shunt defects within solar cells 28, e.g., thin film layers 11, can cause a voltage drop across solar cells 28. In particular, such defects can cause a short circuit across solar cells 28. Thus, controller 160 can compare voltages of solar cells 28 at step 240 to identify solar cells 28 with low voltages that correspond to defects within solar cells 28.

In certain exemplary embodiments, controller 160 can compare voltages of solar cells 28 to one another or to a threshold voltage at step 240. The threshold voltage can correspond to a normal or ideal open circuit voltage of solar cells 28. As discussed above, solar cells 28 containing defects have a lower open circuit voltage than the normal open circuit of solar cells. Thus, solar cells 28 having an open circuit voltage less than the threshold voltage can have defects that cause the voltage across such solar cells 28 to drop.

Method 200 can also include displaying the voltages of solar cells 28. As an example, controller 160 can present the voltages of solar cells 28 in a graph, e.g., similar to the graphs of FIGS. 9 and 10, to a user or operator of apparatus 100 on display 131. By displaying the voltages of solar cells 28, the operator of apparatus 100 can see which solar cells of solar cells 28 contain defects thereby assisting with identifying and locating defects within solar cells 28.

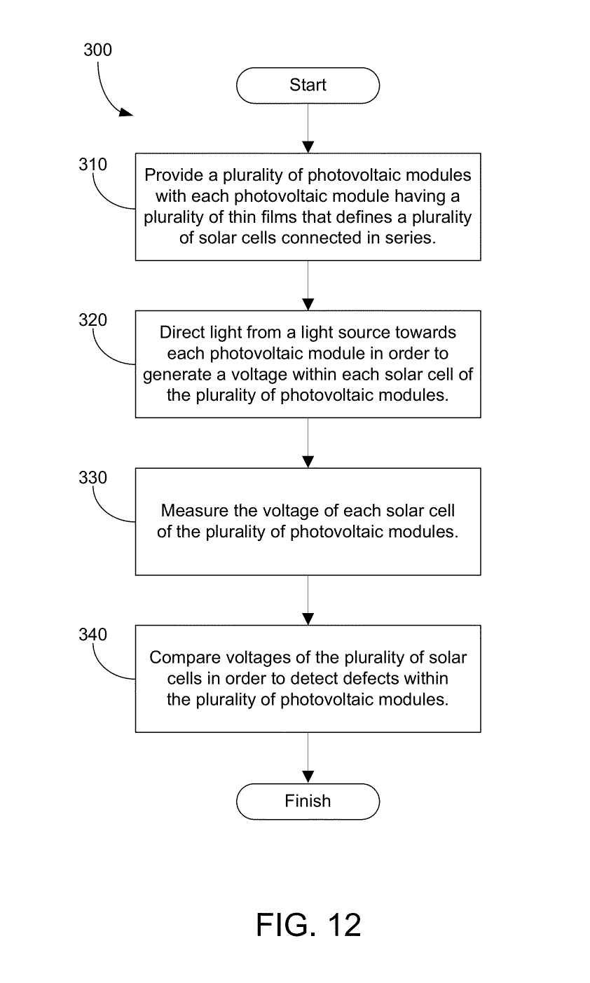

FIG. 12 illustrates a method 300 for detecting defects within a plurality of photovoltaic modules, such as photovoltaic module 10, according to an exemplary embodiment of the present subject matter. Method 300 is similar to method 200 described above. However, method 300 tests a plurality of photovoltaic modules rather than a single photovoltaic module. Thus, each step of method 200 may be repeated for each photovoltaic module of the plurality of photovoltaic modules during method 300. Method 300 can assist with identifying common defects within the plurality of photovoltaic modules, e.g., in order to assist with eliminating shared manufacturing problems. For example, if each photovoltaic module of the plurality of photovoltaic modules has a common defect, the manufacturing step causing the common defect can be identified and eliminated to prevent the common defect from arising in subsequently produced photovoltaic modules.

Thus, method 300 can include locating a defect on one of the solar cells of a particular one of the plurality of photovoltaic modules. Method 300 can also include searching for corresponding defects on solar cells of other photovoltaic modules of the plurality of photovoltaic modules. If corresponding defects are found, eliminating the source of such defects can be easier.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A method for detecting defects within a photovoltaic module having a plurality of thin films that defines a plurality of solar cells connected in series, the method comprising:
directing light from a light source towards the photovoltaic module, the light having an intensity of greater than zero watts per meter squared to about fifty watts per meter squared, the light generating a voltage within at least one solar cell of the photovoltaic module; and,
measuring the voltage of the at least one solar cell of the photovoltaic module.

2. The method of claim 1, further comprising:
comparing the voltage of the at least one solar cell to a threshold voltage in order to detect defects within the photovoltaic module.

3. The method of claim 1, wherein measuring the voltage of the at least one solar cell comprises:
measuring the voltage of each solar cell of the photovoltaic module.

4. The method of claim 3, further comprising:
comparing voltages of the solar cells to one another in order to detect defects within the solar cells of the photovoltaic module.

5. The method of claim 3, further comprising:
comparing voltages of the solar cells to a threshold voltage in order to detect defects within the solar cells of the photovoltaic module.

6. The method of claim 3, further comprising:
providing an additional photovoltaic module having a plurality of thin films that defines a plurality of solar cells connected in series;
directing light from the light source towards the additional photovoltaic module, the light having an intensity greater than zero watts per meter squared and less than about fifty watts per meter squared, the light generating a voltage within at least one solar cell of the additional photovoltaic module; and,
measuring the voltage of each solar cell of the additional photovoltaic module.

7. The method of claim 6, further comprising:
locating a defect on one of the solar cells of the photovoltaic module.

8. The method of claim 7, further comprising:
searching for corresponding defects on solar cells of the additional photovoltaic module.

9. The method of claim 3, further comprising:
displaying the voltages of the solar cells.

10. The method of claim 1, wherein the intensity of the light from the light source is about one watt per meter squared to about ten watts per meter squared.

11. An apparatus for detecting defects within a photovoltaic module, the photovoltaic module having a plurality of thin films that defines a plurality of solar cells connected in series, the apparatus comprising:
a light source configured for directing light having an intensity greater than zero watts per meter squared to about fifty watts per meter squared towards the plurality of solar cells of the photovoltaic module;
a probe head having a plurality of contacts, each contact of the plurality of contacts configured for being positioned in electrical communication with a respective one of the plurality of solar cells of the photovoltaic module; and,
a measuring unit in electrical communication with said probe head, said measuring unit configured for measuring a voltage of each solar cell of the plurality of solar cells.

12. The apparatus of claim 11, wherein said measuring unit comprises a source measurement unit or a multimeter.

13. The apparatus of claim 11, further comprising:
a controller in communication with said measuring unit, said controller configured for:
initiating a scan for defects of the photovoltaic module;
receiving a voltage measurement for each solar cell of the plurality of solar cells from said measuring unit; and,
comparing the voltage measurements to one another or to a threshold voltage in order to detect defects within the plurality of solar cells of the photovoltaic module.

14. The apparatus of claim 13, wherein said probe head is stationary relative to the photovoltaic module during the scan for defects of the photovoltaic module.

15. The apparatus of claim 13, wherein the threshold voltage is about an ideal operating voltage of the plurality of solar cells.

16. The apparatus of claim 11, wherein the intensity of the light from said light source is about one watt per meter squared to about ten watts per meter squared.

17. The apparatus of claim 11, wherein the light source comprises a high intensity light source and a low intensity light source.

18. The apparatus of claim 11, further comprising:
a multiplexer for selectively placing pairs of contacts of the plurality of contacts of said probe head in electrical communication with said measuring device.

19. The apparatus of claim 18, wherein said multiplexer is configured for sequentially placing each pair of contacts of the plurality of contacts in electrical communication with said measuring device.
